(19) United States
(12) Patent Application Publication
(10) Pub. No.: US 2015/0088446 A1
(43) Pub. Date: Mar. 26, 2015

(54) APPARATUS AND METHOD FOR SELECTING WAVEFORM FOR SIDE-CHANNEL ANALYSIS

(71) Applicant: ELECTRONICS AND TELECOMMUNICATIONS RESEARCH INSTITUTE, DAEJEON (KR)

(72) Inventors: Yongdae KIM, Daejeon (KR); Hyuk Joong YOON, Daejeon (KR); Hee Bong CHOI, Daejeon (KR); Haeng Seok KO, Daejeon (KR); Sangwoo PARK, Daejeon (KR)

(21) Appl. No.: 14/340,656

(22) Filed: Jul. 25, 2014

(30) Foreign Application Priority Data
Sep. 25, 2013 (KR) 10-2013-0113928

(51) Int. Cl. G01R 29/08; G01R 19/25

(52) U.S. Cl. CPC G01R 29/0892; G01R 19/2509
USPC 702/71

(57) ABSTRACT

An apparatus and method for selecting a waveform for side-channel analysis are provided. The apparatus for selecting a waveform for side-channel analysis includes a matrix generation unit, a waveform transform unit, and a waveform selection unit. The matrix generation unit generates covariance matrices based on waveforms collected by a waveform collection apparatus. The waveform transform unit determines a 1st principal component using the generated covariance matrices, and to transform the waveforms using the determined 1st principal component. The waveform selection unit selects a waveform for the side-channel analysis from the transformed waveforms.

### CROSS REFERENCE TO RELATED APPLICATION

This application claims the benefit of Korean Patent Application No. 10-2013-0113928, filed Sep. 25, 2013, which is hereby incorporated by reference in its entirety into this application.

### BACKGROUND OF THE INVENTION

1. Technical Field

The present invention relates generally to a method and apparatus for selecting a waveform used for side-channel analysis and, more particularly, to technology that selects a waveform so that the variation value of the waveform is increased using a principal component analysis method, thereby improving the efficiency of side-channel analysis.

2. Description of the Related Art

Side-channel analysis is an analysis method of determining internal information (e.g., a secret key) using leaked information, such as power consumption and electromagnetic waves, from an encryption module. Many side-channel analysis methods have been proposed since the analysis method was first known in the 1990s.

That is, the side-channel analysis method is an attack method of determining the secret information of an encryption algorithm using side-channel information, such as computation time, power consumption and electromagnetic waves, which leaks out when the encryption algorithm is implemented in a low-power information protection apparatus, such as an IC card.

Among such side-channel analysis methods, a side-channel analysis method using correlation coefficients that was introduced in an article “Correlation Power Analysis with a Leakage Model” issued in the year of 2004 is widely used. Thereafter, in the side-channel analysis method using correlation coefficients, a method of selecting a waveform so that the value of a correlation coefficient is increased and performing side-channel analysis has been presented. In such a side-channel analysis method, however, it is necessary to determine which location in a previously measured waveform is a point having the highest correlation coefficient. That is, it is necessary for a person who will perform analysis to find out which point of a waveform will be used through experiments in advance. It is however difficult to determine which point is an optimum point in side-channel analysis. Accordingly, the side-channel analysis method is not suitable for being used as a side-channel analysis method to be applied to other common encryption modules.

Korean Patent Application Publication No. 10-2012-0042002 discloses a technology for determining omitted points in a stored waveform using the collection frequency of the stored waveform to be analyzed and the clock frequency of an apparatus to be analyzed and reducing the number of waveforms based on the determined data, thereby reducing the time it takes to perform side-channel analysis.

### SUMMARY OF THE INVENTION

Accordingly, the present invention has been made keeping in mind the above problems occurring in the conventional art, and an object of the present invention is to provide a method and apparatus for selecting a waveform, which enable precise analysis even using a smaller number of waveforms by selecting a waveform required for side-channel analysis using a principal component analysis method based on a system.

In accordance with an aspect of the present invention, there is provided an apparatus for selecting a waveform for side-channel analysis, including a matrix generation unit configured to generate covariance matrices based on waveforms collected by a waveform collection apparatus; a waveform transform unit configured to determine a 1st principal component using the generated covariance matrices, and to transform the waveforms using the determined 1st principal component; and a waveform selection unit configured to select a waveform for the side-channel analysis from the transformed waveforms.

The waveform transform unit may calculate eigenvectors and eigenvalues based on the generated covariance matrices, and may determine an eigenvector corresponding to a greatest eigenvalue to be the 1st principal component.

The waveform selection unit may align the transformed waveforms, and may select the waveform for the side-channel analysis.

The waveform selection unit may align the transformed waveforms in descending order, and may select the waveform so that a variation value of the selected waveform is higher than the variation values of all the collected waveforms.

In accordance with another aspect of the present invention, there is provided a method of selecting a waveform for side-channel analysis, including generating covariance matrices based on waveforms collected by a waveform collection apparatus; determining a 1st principal component using the generated covariance matrices; transforming the waveforms using the determined 1st principal component; and selecting a waveform for the side-channel analysis from the transformed waveforms.

Determining the 1st principal component may include calculating eigenvectors and eigenvalues based on the generated covariance matrices; and determining an eigenvector corresponding to a greatest eigenvalue to be the 1st principal component.

Selecting the waveform may include aligning the transformed waveforms and selecting the waveform for the side-channel analysis.

Selecting the waveform may include aligning the transformed waveforms in descending order; and selecting the waveform from the waveforms aligned in descending order so that a variation value of the selected waveform is higher than variation values of all the collected waveforms.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a block diagram of a side-channel analysis system according to an embodiment of the present invention;

FIG. 2 is a diagram illustrating a typical side-channel analysis method;

FIG. 3 is a block diagram of the waveform selection apparatus of the side-channel analysis system of FIG. 1 according to an embodiment of the present invention;

FIGS. 4 and 5 are diagrams illustrating the waveform selection apparatus of FIG. 3; and

FIG. 6 is a flowchart illustrating a waveform selection method according to an embodiment of the present invention.

### DESCRIPTION OF THE PREFERRED EMBODIMENTS

Reference now should be made to the drawings, throughout which the same reference numerals are used to designate the same or similar components.

Embodiments of an apparatus and method for selecting a waveform for side-channel analysis and a side-channel analysis system are described in detail with reference to the accompanying drawings.

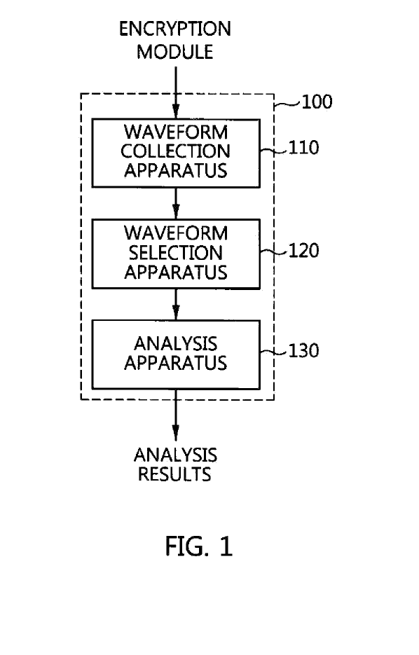

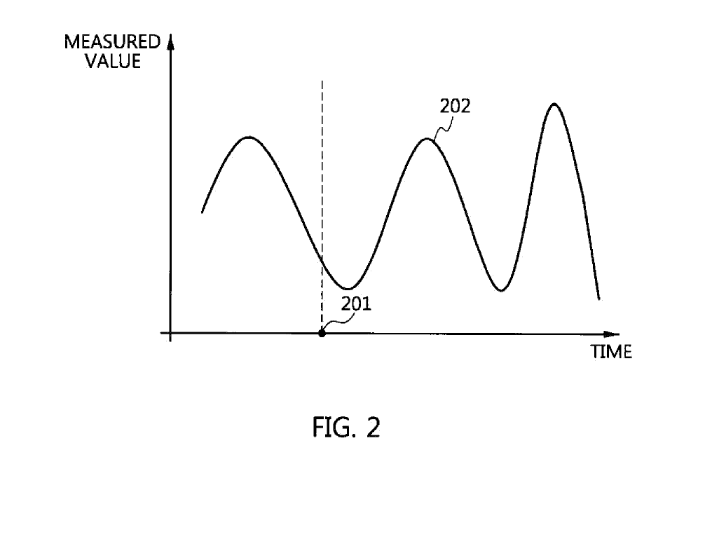

FIG. 1 is a block diagram of the side-channel analysis system according to an embodiment of the present invention, and FIG. 2 is a diagram illustrating a typical side-channel analysis method.

Referring to FIG. 1, the side-channel analysis system 100 may include a waveform collection apparatus 110, a waveform selection apparatus 120, and an analysis apparatus 130.

The waveform collection apparatus 110 collects waveforms by measuring leaked information, such as power consumption or electromagnetic waves that leak out from an encryption module.

The waveform selection apparatus 120 may select a waveform for side-channel analysis using the waveforms collected by the waveform collection apparatus 110.

FIG. 2 is an example of a waveform 202 that is used to illustrate an existing method of selecting a waveform in a typical side-channel analysis method. Referring to FIG. 2, in the typical side-channel analysis method, the existing method of selecting a waveform is limited in that only a single optimum point 201 in the measured waveform 202 needs to be known in advance.

In accordance with an embodiment of the present invention, however, a waveform may be systematically selected without knowing the optimum point 201 in advance, as illustrated in FIG. 2.

In accordance with an embodiment of the present invention, the waveform selection apparatus 120 may generate covariance matrices based on collected waveforms, and may select a required waveform using the generated covariance matrices. In this case, the waveform selection apparatus 120 may calculate eigenvectors and eigenvalues based on the generated covariance matrices, and may select a waveform so that the variation value of the selected waveform is increased using the eigenvectors and eigenvalues. However, the present invention is not limited to such a method. For example, a waveform may be selected so that the variation value of the waveform decreases.

The analysis apparatus 130 generates results by performing side-channel analysis using the selected waveform.

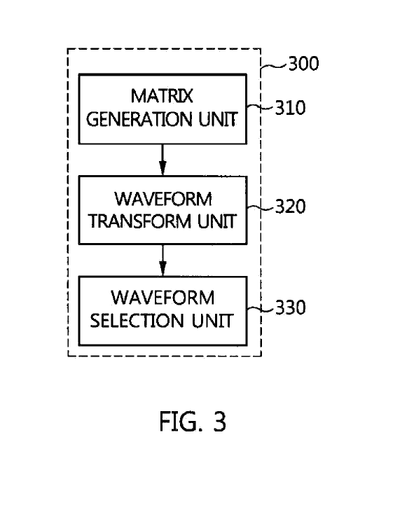

FIG. 3 is a block diagram of the waveform selection apparatus of the side-channel analysis system of FIG. 1 according to an embodiment of the present invention.

The waveform selection apparatus 300 of FIG. 3 may be an example of the waveform selection apparatus 120 of the side-channel analysis system 100 of FIG. 1 according to an embodiment of the present invention.

The waveform selection apparatus 300 according to this embodiment of the present invention is described in more detail with reference to FIG. 3.

Referring to FIG. 3, the waveform selection apparatus 300 may include a matrix generation unit 310, a waveform transform unit 320, and an analysis selection unit 330.

The matrix generation unit 310 generates covariance matrices using waveforms collected by the waveform collection apparatus.

For example, assuming that N waveforms have been collected by the waveform collection apparatus and T points are present in the respective N collected waveforms, the matrix generation unit 310 may generate a total of N×T covariance matrices.

The waveform transform unit 320 may determine a 1st principal component using the covariance matrices generated by the matrix generation unit 310, and may transform the waveforms using the determined 1st principal component.

In this case, in accordance with an embodiment, the waveform transform unit 320 may calculate eigenvectors and eigenvalues based on covariance matrices N×T generated with respect to the N collected waveforms, and may determine an eigenvector corresponding to the greatest eigenvalue to be the 1st principal component.

The waveform transform unit 320 may obtain N×1 transformed waveforms by transforming the N×T waveforms using the 1st principal component determined as described above.

The waveform selection unit 330 may align the N×1 transformed waveforms in ascending or descending order, and may select a waveform for side-channel analysis.

If the transformed waveforms are aligned in ascending order and a waveform is selected as described above, the variation value of the selected waveform decreases and thus side-channel analysis may be influenced. In contrast, if the transformed waveforms are aligned in descending order and a waveform is selected, the variation value of the selected waveform is increased and thus side-channel analysis may be influenced.

In accordance with an embodiment of the present invention, the transformed waveforms may be aligned in descending order and a waveform may be selected so that the variation value of the selected waveform is increased, thereby improving the efficiency of side-channel analysis. However, the present invention is not limited to such a method. For example, the transformed waveforms may be aligned in ascending order, and a waveform may be selected so that the variation value of the selected waveform is decreased.

In general, side-channel analysis is performed using multiple waveforms because information, such as noise, is included in the waveforms. Accordingly, excessively long computation time and a high amount of memory for computation are required because multiple waveforms are used for side-channel analysis as described above.

According to an embodiment of the present invention, however, the computation time and memory for computation can be reduced because the number of waveforms for side-channel analysis can be systematically reduced.

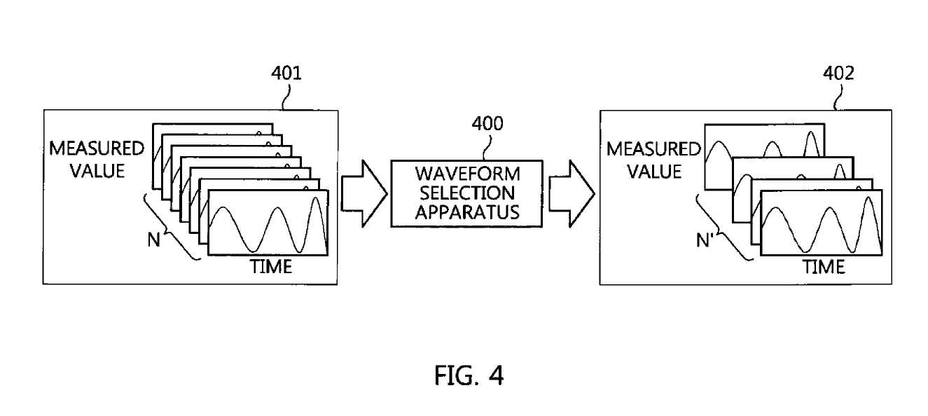

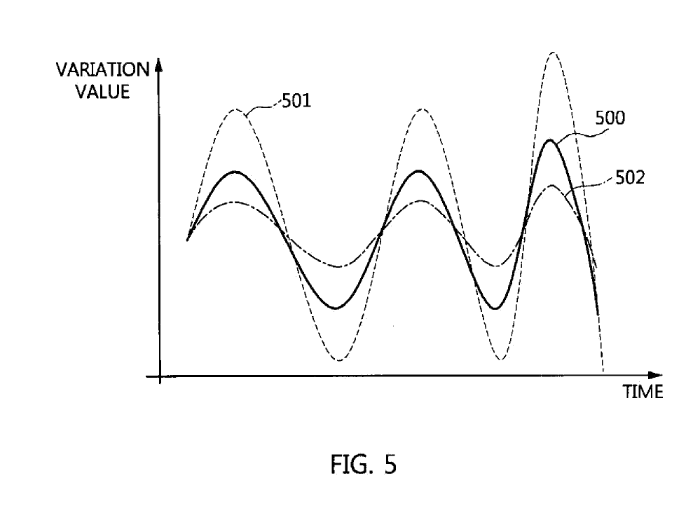

FIGS. 4 and 5 are diagrams illustrating the waveform selection apparatus of FIG. 3.

FIG. 4 illustrates the results of waveforms for side-channel analysis selected by the waveform selection apparatus 400. When N waveforms 401 are collected by the waveform collection apparatus, the waveform selection apparatus 400 may select N′ (N′<N) waveforms 402 to be applied to side-channel analysis so that the variation values of the selected waveforms are increased or decreased as described above.

FIG. 5 is a diagram illustrating a comparison between the variation values of selected waveforms when collected waveforms are aligned in descending or ascending order and the waveforms are selected.

In FIG. 5, reference numeral 500 designates the variation values of all collected waveforms before some waveforms are selected, reference numeral 501 designates the variation values of some waveforms selected by the waveform selection apparatus after transformed waveforms have been aligned in descending order, and reference numeral 502 designates the variation values of some waveforms selected by the waveform selection apparatus after transformed waveforms have been aligned in ascending order.

Referring back to FIG. 3, the waveform selection apparatus 300 may align transformed waveforms in descending order, select some waveforms so that the variation values of the selected waveforms are higher than the variation values of all collected waveforms, as illustrated in FIG. 5, and input the selected waveforms to the side-channel analysis apparatus 130 of FIG. 1.

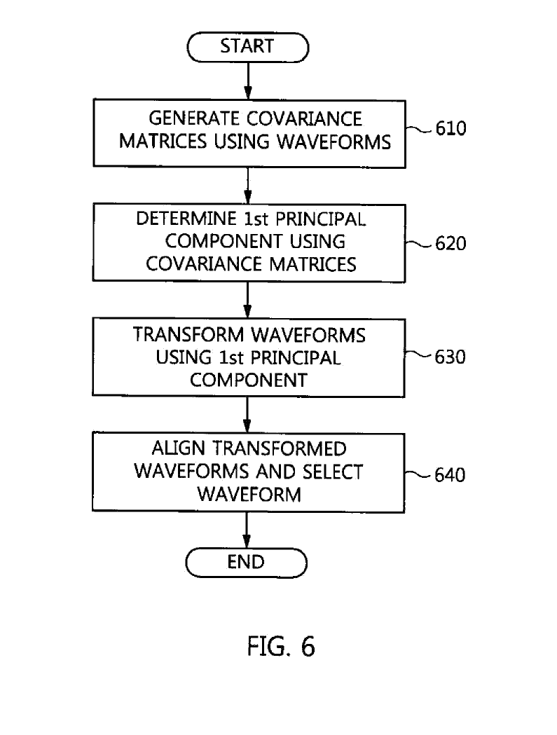

FIG. 6 is a flowchart illustrating a waveform selection method according to an embodiment of the present invention.

The waveform selection method of FIG. 6 may be an example of a waveform selection method performed by the waveform selection apparatus 300 of FIG. 3 according to an embodiment of the present invention.

The waveform selection method according to an embodiment of the present invention is described with reference to FIG. 6. The waveform selection apparatus 300 may generate covariance matrices using waveforms collected by the waveform collection apparatus at step 610.

As described with reference to FIG. 4, when the waveform collection apparatus collects the N waveforms 401, the waveform selection apparatus 300 may generate the total of N×T covariance matrices corresponding to the T points that are present in the respective waveforms 401.

The waveform selection apparatus 300 may generate a 1st principal component using the generated covariance matrices at step 620. In this case, the waveform selection apparatus 300 may calculate eigenvectors and eigenvalues based on the covariance matrices N×T generated in relation to the N collected waveforms, and may determine an eigenvector corresponding to the greatest eigenvalue to be the 1st principal component.

The waveform selection apparatus 300 may obtain the N×1 transformed waveforms by transforming N×T waveforms using the determined 1st principal component at step 630.

The waveform selection apparatus 300 may align the N×1 transformed waveforms in ascending or descending order and select a waveform for side-channel analysis at step 640. In this case, in accordance with an embodiment of the present invention, when the transformed waveforms are aligned in descending order and a waveform is selected so that the variation value of the selected waveform is increased, the efficiency of side-channel analysis can be improved.

As described above, since a waveform required for side-channel analysis is selected using a principal component analysis method based on a system, the number of waveforms required for the side-channel analysis can be reduced, and precise analysis can be performed using a smaller number of waveforms.

Although the preferred embodiments of the present invention have been disclosed for illustrative purposes, those skilled in the art will appreciate that various modifications, additions and substitutions are possible without departing from the scope and spirit of the invention as disclosed in the accompanying claims.

What is claimed is:

1. An apparatus for selecting a waveform for side-channel analysis, comprising:
a matrix generation unit configured to generate covariance matrices based on waveforms collected by a waveform collection apparatus;
a waveform transform unit configured to determine a 1st principal component using the generated covariance matrices, and to transform the waveforms using the determined 1st principal component; and
a waveform selection unit configured to select a waveform for the side-channel analysis from the transformed waveforms.

2. The apparatus of claim 1, wherein the waveform transform unit calculates eigenvectors and eigenvalues based on the generated covariance matrices, and determines an eigenvector corresponding to a greatest eigenvalue to be the 1st principal component.

3. The apparatus of claim 1, wherein the waveform selection unit aligns the transformed waveforms, and selects the waveform for the side-channel analysis.

4. The apparatus of claim 3, wherein the waveform selection unit aligns the transformed waveforms in descending order, and selects the waveform so that a variation value of the selected waveform is higher than variation values of all the collected waveforms.

5. A method of selecting a waveform for side-channel analysis, comprising:
generating covariance matrices based on waveforms collected by a waveform collection apparatus;
determining a 1st principal component using the generated covariance matrices;
transforming the waveforms using the determined 1st principal component; and
selecting a waveform for the side-channel analysis from the transformed waveforms.

6. The method of claim 5, wherein determining the 1st principal component comprises:
calculating eigenvectors and eigenvalues based on the generated covariance matrices; and
determining an eigenvector corresponding to a greatest eigenvalue to be the 1st principal component.

7. The method of claim 5, wherein selecting the waveform comprises aligning the transformed waveforms and selecting the waveform for the side-channel analysis.

8. The method of claim 7, wherein selecting the waveform comprises:
aligning the transformed waveforms in descending order; and
selecting the waveform from the waveforms aligned in descending order so that a variation value of the selected waveform is higher than variation values of all the collected waveforms.
